(19) United States
(12) Patent Application Publication
(10) Pub. No.: US 2026/0047082 A1
(43) Pub. Date: Feb. 12, 2026

(54) MEMORY DEVICE AND MANUFACTURING METHOD THEREOF

(71) Applicant: Yangtze Memory Technologies Co., Ltd., Wuhan (CN)

(72) Inventors: Yali GUO, Wuhan (CN); Bin YUAN, Wuhan (CN); Wei XU, Wuhan (CN); Bo XU, Wuhan (CN); Fan GONG, Wuhan (CN); Zongliang HUO, Wuhan (CN)

(21) Appl. No.: 18/921,767

(22) Filed: Oct. 21, 2024

(30) Foreign Application Priority Data
Aug. 9, 2024 (CN) 202411096504.8

(51) Int. Cl. H10B 12/00

(52) U.S. Cl. CPC H10B 12/50

(57) ABSTRACT

The present disclosure provides a memory device and a manufacturing method thereof. The memory device includes first, second and third semiconductor bodies that each extend in a first and a second direction and are arranged in a third direction, and a first conductive line extending in the third direction. The first and the second semiconductor bodies are located on a same side of two opposite sides of the third semiconductor body in the third direction. The first conductive line is at least located on one of two opposite sides of the first, second and third semiconductor bodies in the second direction. A size of the third semiconductor body in the second direction is greater than a size of the second semiconductor body in the second direction, and is smaller than a size of the first semiconductor body in the second direction.

### CROSS-REFERENCE TO RELATED APPLICATIONS

This application claims the benefit of priority to Chinese Patent Application No. 202411096504.8, filed on Aug. 9, 2024, the disclosure of which is hereby incorporated by reference in its entirety.

### TECHNICAL FIELD

The present disclosure relates to the field of semiconductor technology, for example, to a memory device and a manufacturing method thereof.

### BACKGROUND

With the continuous development of science and technology, semiconductor devices are widely applied in various electronic apparatuses and electronic products. For example, a dynamic random access memory (DRAM) as a volatile memory is a commonly used semiconductor memory device in computers.

### SUMMARY

According to a first aspect of examples of the present disclosure, a memory device is provided, which comprises a first semiconductor body, a second semiconductor body and a third semiconductor body that each extend in a first direction and a second direction and are arranged in a third direction, and a first conductive line extending in the third direction, wherein the first semiconductor body and the second semiconductor body are located on a same side of two opposite sides of the third semiconductor body in the third direction; the first conductive line is at least located on one of two opposite sides of the first semiconductor body, the second semiconductor body and the third semiconductor body in the second direction; a size of the third semiconductor body in the second direction is greater than a size of the second semiconductor body in the second direction, and is less than a size of the first semiconductor body in the second direction; and the second direction intersects the third direction, and both the second direction and the third direction are perpendicular to the first direction.

According to a second aspect of examples of the present disclosure, a memory device is provided, which comprises a first region and a second region, wherein the first region comprises a plurality of first semiconductor bodies and a plurality of second semiconductor bodies; the second region comprises a plurality of third semiconductor bodies; the plurality of first semiconductor bodies, the plurality of second semiconductor bodies and the plurality of third semiconductor bodies each extend in a first direction and a second direction and are arranged in a third direction; the plurality of first semiconductor bodies and the plurality of second semiconductor bodies are arranged alternately in the third direction; the first region and the second region are arranged in juxtaposition in the third direction; the first region and the second region further comprise first conductive lines extending in the third direction; the first conductive lines are at least located on one of two opposite sides of the plurality of first semiconductor bodies, the plurality of second semiconductor bodies and the plurality of third semiconductor bodies in the second direction; the second direction intersects the third direction, and both the second direction and the third direction are perpendicular to the first direction; and a distance between two adjacent ones of the third semiconductor bodies in the second region is greater than a distance between the first semiconductor body and the second semiconductor body that are adjacent to each other in the first region.

According to a third aspect of examples of the present disclosure, a manufacturing method of a memory device is provided, which comprises: forming a first semiconductor body, a second semiconductor body and a third semiconductor body that each extend in a first direction and a second direction and are arranged in a third direction, and a first conductive line extending in the third direction, wherein the first semiconductor body and the second semiconductor body are located on a same side of two opposite sides of the third semiconductor body in the third direction; the first conductive line is at least located on one of two opposite sides of the first semiconductor body, the second semiconductor body and the third semiconductor body in the second direction; a size of the third semiconductor body in the second direction is greater than a size of the second semiconductor body in the second direction, and is less than a size of the first semiconductor body in the second direction; and the second direction intersects the third direction, and both the second direction and the third direction are perpendicular to the first direction.

In the technical solutions provided by the present disclosure, the first semiconductor body, the second semiconductor body and the third semiconductor body that extend in the first direction and the second direction and are arranged in the third direction have different sizes in the second direction; the first semiconductor body and the second semiconductor body are located on the same side of two opposite sides of the third semiconductor body in the third direction, and the size of the third semiconductor body in the second direction is greater than the size of the second semiconductor body in the second direction and is less than the size of the first semiconductor body in the second direction. In the examples of the present disclosure, on the basis of reserving a certain space for a conductive connection structure, an environmental difference between a region where the third semiconductor body is located and a region where the second semiconductor body and the first semiconductor body are located is reduced, such that the etch loading effect may be improved during formation of the semiconductor body by etching.

### BRIEF DESCRIPTION OF THE DRAWINGS

FIG. 1 is a diagram of an electronic apparatus provided by examples of the present disclosure.

FIG. 2 is a diagram of a DRAM provided by examples of the present disclosure.

FIG. 3 is a composition structural diagram of a memory device provided by examples of the present disclosure.

FIG. 4 is a composition structural diagram I of a memory block provided by examples of the present disclosure.

FIG. 5 is a top structural diagram of a semiconductor body in a transistor of a memory cell at a corner of a memory block or a memory bank.

FIG. 6 is a partial top structural diagram I of a memory device provided by examples of the present disclosure.

FIG. 7 is a partial perspective structural diagram of a memory device provided by examples of the present disclosure.

FIG. 8 is a partial top structural diagram II of a memory device provided by examples of the present disclosure.

FIG. 9 is a partial top structural diagram III of a memory device provided by examples of the present disclosure.

FIG. 10 is a partial top structural diagram IV of a memory device provided by examples of the present disclosure.

FIG. 11 is a partial top structural diagram V of a memory device provided by examples of the present disclosure.

FIG. 12 is a composition structural diagram II of a memory block provided by examples of the present disclosure.

FIG. 13 is a partial cross-sectional structural diagram I of a memory device provided by examples of the present disclosure.

FIG. 14 is a partial top structural diagram VI of a memory device provided by examples of the present disclosure.

FIG. 15 is a partial top structural diagram VII of a memory device provided by examples of the present disclosure.

FIG. 16 is a partial cross-sectional structural diagram II of a memory device provided by examples of the present disclosure.

FIG. 17 is a flow diagram of a fabrication method of a memory device provided by examples of the present disclosure.

FIGS. 18 to 27 are structural diagrams of a fabrication process of a memory device provided by examples of the present disclosure.

### DETAILED DESCRIPTION

Example implementations disclosed in the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described herein, and well-known functions and structures are not described in detail.

In the drawings, like reference numerals denote like elements throughout the specification.

It is to be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is turned over, then the elements or the features described as “below” or “under” or “beneath” other elements may be oriented “on” the other elements or features. Thus, the example terms, “below” and “beneath”, may comprise both upper and lower orientations. The device may be orientated otherwise (rotated by 90 degrees or in other orientations), and the spatially descriptive terms used herein are interpreted accordingly.

The terms used herein are only intended to describe the particular examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, indicate the presence of the described features, integers, steps, operations, elements and/or components, but do not preclude the presence or addition of one or more of other features, integers, steps, operations, elements, components, and/or groups. As used herein, the term “and/or”comprises any or all combinations of the listed relevant items.

FIG. 1 is a diagram of an electronic apparatus provided by examples of the present disclosure. The electronic apparatus 1 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memories therein.

As shown in FIG. 1, the electronic apparatus 1 may comprise a memory system 10 and a host 20. The memory system 10 may comprise a controller 110 and a memory 120. The host 20 may comprise a processor of the electronic apparatus 1, e.g., a central processing unit (CPU) or a system on chip (SoC) (e.g., an application processor (AP)). The controller 110 is coupled with both the host 20 and the memory 120. The controller 110 may be configured to communicate with the host 20 and control the memory 120.

In some examples, the controller 110 may be configured to control operations of the memory 120, such as a read operation, an erase operation, a write operation, a refresh operation and the like. In some implementations, the controller 110 is further configured to process an error correction code (ECC) with respect to the data read from or written to the memory 120. In some other examples, the controller 110 may be further configured to perform any other suitable operations, for example, formatting the memory 120.

In some examples, the controller 110 may receive data, commands and addresses from the host 20 and may send data, commands and addresses to the memory 120. In an example, the controller 110 may comprise a command generator 111, an address generator 112, an apparatus interface 113, and a host interface 114. The controller 110 may receive data, commands and addresses from the host 20 through the host interface 114 and decode the command received from the host 20 through the command generator 111 to generate an access command CMD, and may provide the access command CMD to the memory 120 through the apparatus interface 113. The controller 110 may decode the address received from the host interface 114 through the address generator 112 to generate an address ADDR to be accessed in a memory array 121, and may provide the address ADDR to be accessed to the memory 120 through the apparatus interface 113. The access command may be a signal that instructs the memory 120 to write or read data by accessing one or more memory cells in the memory array 121 corresponding to the address ADDR. Moreover, the controller 110 may send a refresh command to the memory 120. The refresh command may be a signal that instructs the memory 120 to read and re-write data by accessing one or more memory cells in the memory array 121 corresponding to the address ADDR.

In some particular examples, the memory 120 may be a Random Access Memory (RAM), e.g., a dynamic random memory, a Synchronous Dynamic Random Access Memory (SDRAM), a Static Random Access Memory (SRAM), a Dual Date Rate SDRAM (DDR SDRAM), a Phase-change Random Access Memory (PRAM), a Resistive Random Access Memory (ReRAM), a Magnetic Random Access Memory (MRAM), and the like. In the following, the memory 120 as the DRAM is illustrated as an example.

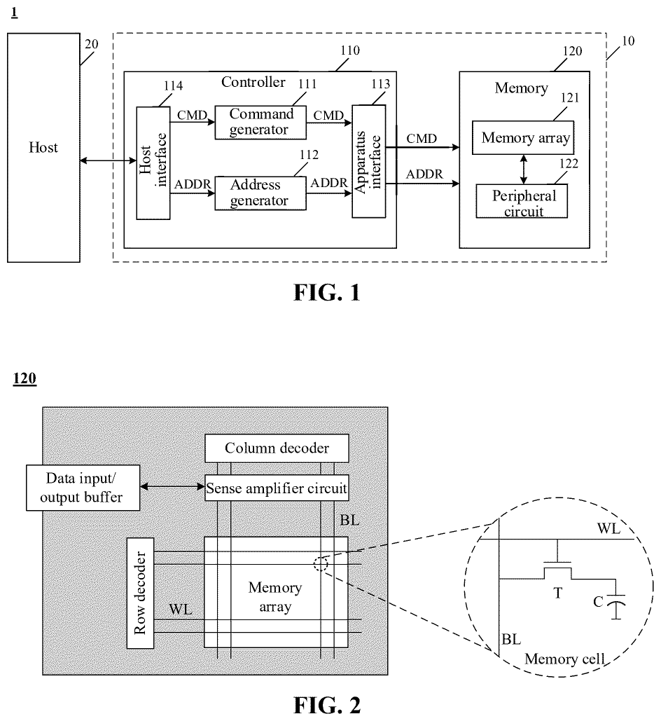

In some examples, FIG. 2 is a diagram of a DRAM illustrated according to examples of the present disclosure. With reference to FIGS. 1 and 2, the DRAM comprises a memory array 121 and a peripheral circuit 122 coupled with the memory array 121. The peripheral circuit 122 may comprise a sense amplifier circuit, a row decoder, a column decoder, a data input/output buffer, and the like. The memory array 121 comprises a plurality of memory cells arranged in an array. A plurality of memory cells in the same row are coupled with a word line WL, and a plurality of memory cells in the same column are coupled with a bit line BL. Each memory cell comprises one transistor T and one capacitor C. The word line WL is connected with a gate of the transistor T. The bit line BL is connected with one of a source and a drain of the transistor T. The other one of the source and the drain of the transistor T is connected with one electrode of the capacitor C. The other electrode of the capacitor C is connected with a fixed voltage. The memory cell is configured to store 1 or 0 using the amount of charges stored in the capacitor C. By designating a row address and a column address, each memory cell in a DRAM chip may be independently accessed, and a read operation, a write perform or a refresh operation may be performed on the data stored therein.

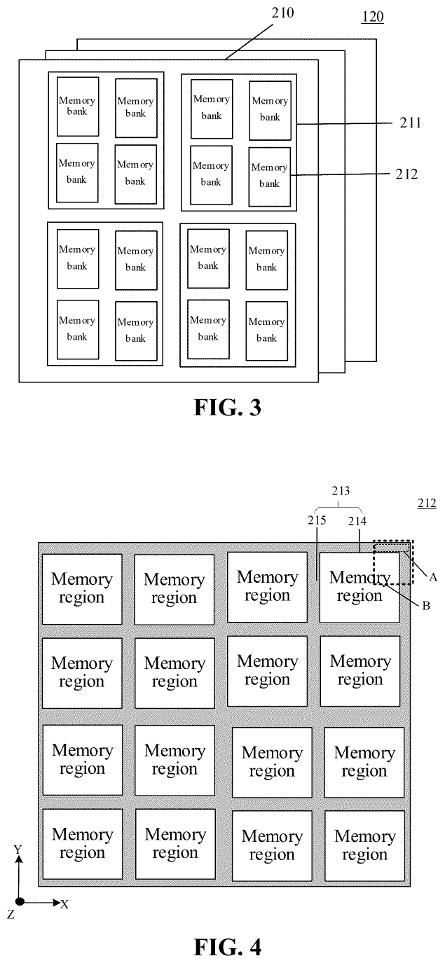

As shown in FIGS. 3 and 4, a memory 120 comprises at least one chip 210 that comprises at least one memory bank group 211. Each memory bank group 211 comprises at least one memory bank 212, and each memory bank 212 comprises at least one memory block 213. Each memory block comprises a memory region 214 and a dummy region 215. The dummy region 215 is located at an edge region of the memory block, and may be located on two opposite sides of the memory region 214 in an X direction and on two opposite sides of the memory region in a Y direction. Memory cells in the memory region 214 may be used for storage, while memory cells in the dummy region 215 may be not used for storage.

In some examples, each memory block comprises a plurality of rows of memory cells arranged in the Y direction and a plurality of columns of memory cells arranged in an axial direction. Each row of memory cells is coupled with one corresponding word line, and each column of memory cells is coupled with one corresponding bit line. The word lines of the adjacent memory blocks are separated by a corresponding isolation structure, and the bit lines of the adjacent memory blocks are separated by a corresponding isolation structure. The word lines of the adjacent memory banks are separated by a corresponding isolation structure, and the bit lines of the adjacent memory banks are separated by a corresponding isolation structure.

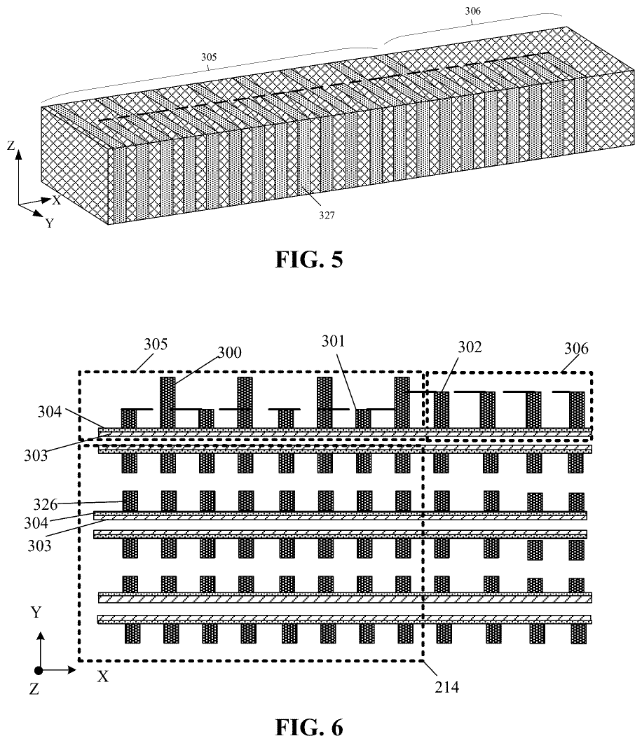

FIG. 5 is a top structural diagram of a semiconductor body in a transistor of a memory cell at a corner of a memory block or a memory bank. In an example, FIG. 5 may illustrate a structure at a dashed box A in FIG. 4. A portion of the dummy region of the memory block close to a corner is at the dashed box in FIG. 4. As shown in FIG. 5, the dummy region of the memory block close to the corner comprises a first region 305 and a second region 306 arranged in the X direction, and the second region 306 is a region close to the edge. As can be seen from FIG. 5, a plurality of semiconductor bodies 327 arranged in the first region and the second region in the X direction have different sizes in the Y direction. In an example, the semiconductor bodies 327 in the first region 305 have varied sizes in the Y direction, and the long semiconductor bodies and the short semiconductor bodies are arranged alternately in the X direction. In order to reserve a space for disposing a corresponding conductive connection structure, the size of the semiconductor body in the second region 306 at the edge in a Y axis direction is shorter, and is equal to the size of the short semiconductor body in the first region 305 in the Y axis direction.

In some examples, the semiconductor body and the word line in the above-mentioned memory may be formed by the following: etching a semiconductor layer from a first side of the semiconductor layer to form a plurality of semiconductor bodies arranged in an array in the X direction and the Y direction and form an initial word line from the first side of the semiconductor layer; and then thinning the semiconductor layer from a second side of the semiconductor layer to cut off the initial word line, such that one initial word line forms two corresponding word lines, and the first side and the second side are two opposite surfaces of the semiconductor layer in a thickness direction of the semiconductor layer. On the one hand, as shown in FIG. 5, the dummy region (the second region) at the corner of the memory block or the dummy region (the second region) at the corner of the memory bank have only the short semiconductor bodies, and the semiconductor bodies in the dummy region (the second region) in a middle portion have varied lengths. On the other hand, the dummy region at the corner of the memory block or the dummy region at the corner of the memory bank has many isolation structures, such that there is a large difference between the dummy region at the corner of the memory block or the dummy region at the corner of the memory bank and a surrounding environment. Therefore, during the etching of the semiconductor layer to form the semiconductor body, there is a large difference in the etch loading effect of different regions, and an etching depth in the dummy region at the corner is less than an etching depth in the dummy region in the middle portion, so that when the semiconductor layer is thinned from the second side of the semiconductor layer, the semiconductor layer between the adjacent semiconductor bodies in the dummy region at the corner of the memory block or the dummy region at the corner of the memory bank is not worn away, thereby affecting cutting off of the initial word line in a subsequent process.

In this regard, the present disclosure provides the following implementations.

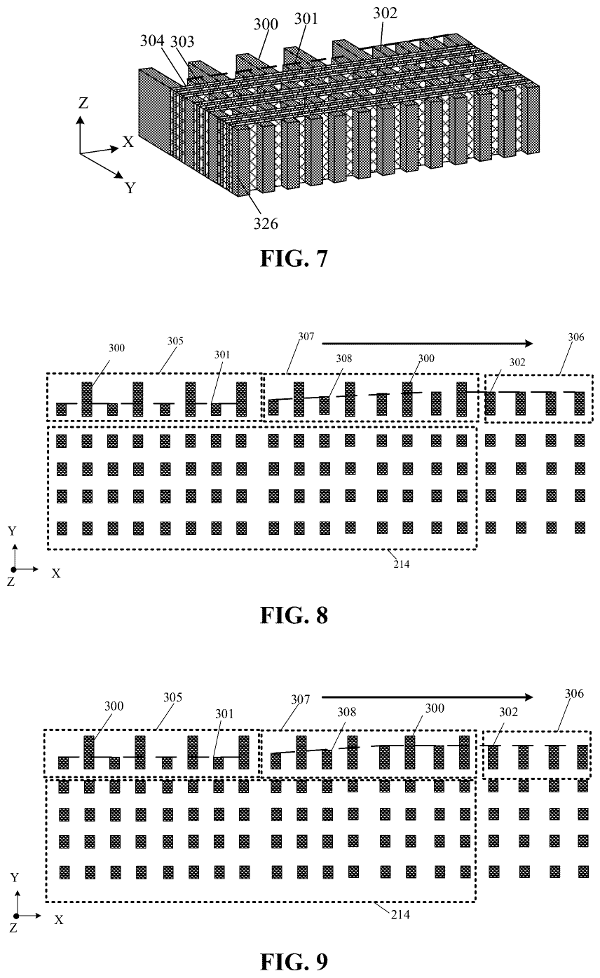

Examples of the present disclosure provide a memory device. FIG. 6 is a partial top structural diagram of a memory device provided by the examples of the present disclosure, and FIG. 7 is a partial perspective structural diagram of a memory device provided by the examples of the present disclosure. As shown in FIGS. 6 and 7, the memory device comprises a first semiconductor body 300, a second semiconductor body 301 and a third semiconductor body 302 that extend in a first direction and a second direction and are arranged in a third direction, and a first conductive line 303 extending in the third direction. The first semiconductor body 300 and the second semiconductor body 301 are located on the same side of two opposite sides of the third semiconductor body 302 in the third direction; the first conductive line 303 is at least located on one of two opposite sides of the first semiconductor body 300, the second semiconductor body 301 and the third semiconductor body 302 in the second direction; the size of the third semiconductor body 302 in the second direction is greater than the size of the second semiconductor body 301 in the second direction, and is less than the size of the first semiconductor body 300 in the second direction; and the second direction intersects the third direction, and both the second direction and the third direction are perpendicular to the first direction.

FIGS. 6 and 7 may be the structural diagrams at a dashed box B in FIG. 4.

It is to be noted that the third semiconductor body may be not only located at an edge region of a memory bank, and the above examples may not only optimize the edge region of the memory bank accordingly. The third semiconductor body may be also located at an edge region of a memory block in the memory bank, and the above examples may also optimize the edge region of the memory block in the memory bank accordingly. Moreover, the third semiconductor body may be located at the edge regions of at least some of a plurality of memory blocks in the memory bank, and may be located in an interior region of the memory bank.

In the examples of the present disclosure, the first semiconductor body 300, the second semiconductor body 301 and the third semiconductor body 302 that extend in the first direction and the second direction and are arranged in the third direction have different sizes in the second direction; the first semiconductor body 300 and the second semiconductor body 301 are located on the same side of two opposite sides of the third semiconductor body 302 in the third direction, and the size of the third semiconductor body 302 in the second direction is greater than the size of the second semiconductor body 301 in the second direction and less than the size of the first semiconductor body 300 in the second direction. In the examples of the present disclosure, on the basis of reserving a certain space for a conductive connection structure, an environmental difference between a region where the third semiconductor body is located and a region where the second semiconductor body and the first semiconductor body are located is reduced, such that the etch loading effect may be improved during formation of the semiconductor body by etching.

In the examples of the present disclosure, the first direction may be a Z axis direction shown in the figures, the second direction may be a Y axis direction shown in the figures, and the third direction may be an X axis direction shown in the figures.

In some particular examples, materials of the first semiconductor body 300, the second semiconductor body 301, the third semiconductor body 302, and a fourth semiconductor body hereinafter include, but are not limited to, an elemental semiconductor material (e.g., silicon (Si) or germanium (Ge), etc.), a group III-V compound semiconductor material (e.g., gallium nitride (GaN), gallium arsenide (GaAs), or indium phosphide (InP), etc.), a group II-VI compound semiconductor material (e.g., zinc sulfide (ZnS), cadmium sulfide (CdS) or cadmium telluride (CdTe), etc.), an organic semiconductor material or other semiconductor materials known in the art. The materials of the first semiconductor body 300, the second semiconductor body 301, the third semiconductor body 302 and the fourth semiconductor body are the same.

In the examples of the present disclosure, the semiconductor bodies extend in the Z direction, and a transistor of a memory cell in the examples of the present disclosure is a vertical transistor. The semiconductor body comprises a source, a channel region and a drain arranged in the Z direction, and the first conductive line 303 is located on one of two opposite sides of the channel region in the Y direction. As shown in FIGS. 6 and 7, the memory device in the examples of the present disclosure further comprises a plurality of fifth semiconductor bodies 326 in the memory region 214. The plurality of fifth semiconductor bodies 326 are arranged in an array in the second direction and the third direction and each extend in the first direction, and the sizes of the plurality of fifth semiconductor bodies 326 in the second direction may be equal. The memory device in the examples of the present disclosure further comprises a plurality of first conductive lines 303 that are arranged in the second direction and each extend in the third direction in the memory region 214. The first conductive lines 303 in the memory region 214 are at least located on one of two opposite sides in the second direction of the plurality of fifth semiconductor bodies 326 arranged in the third direction. The first conductive line 303 may be a word line. It is to be noted that, as an example in both FIGS. 6 and 7, the first conductive lines 303 are located on one of two opposite sides in the second direction of the plurality of fifth semiconductor bodies 326 arranged in the third direction and the first conductive line is at least located on one of two opposite sides of the first semiconductor body, the second semiconductor body and the third semiconductor body in the second direction. However, the present disclosure is not limited thereto.

In some particular examples, a material of the first conductive line 303 comprises a conductive material, e.g., at least one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some particular examples, as shown in FIGS. 6 and 7, a gate dielectric layer 304 is further disposed between the first conductive line 303 and a corresponding semiconductor body, and may be located between the first conductive line 303 and the channel region of the corresponding semiconductor body. The gate dielectric layer 304 may comprise at least one of a high dielectric constant material, silicon oxide, silicon nitride and silicon oxynitride, and the high dielectric constant material may comprise at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some examples, as shown in FIGS. 6 and 7, the memory device comprises a first region 305 and a second region 306 arranged in juxtaposition in the third direction, and the memory device comprises a plurality of first semiconductor bodies 300, a plurality of second semiconductor bodies 301 and a plurality of third semiconductor bodies 302 arranged in the third direction. The plurality of first semiconductor bodies 300 and the plurality of second semiconductor bodies 301 are located in the first region 305; the plurality of third semiconductor bodies 302 are located in the second region 306; and the plurality of first semiconductor bodies 300 and the plurality of second semiconductor bodies 301 are arranged alternately in the third direction.

In the examples of the present disclosure, the plurality of first semiconductor bodies 300 and the plurality of second semiconductor bodies 301 in the first region 305 are arranged alternately in the third direction, that is to say, the long and short semiconductor bodies are arranged alternately, to enable a more flexible subsequent disposition of the conductive connection structure. It is to be noted that the present disclosure is also applicable to a case where the size of the first semiconductor body in the first region in the second direction is equal to the size of the second semiconductor body in the second direction.

In some examples, the memory device comprises a plurality of memory banks, wherein the second region 306 is a region at a corner of the memory bank; or the memory device comprises a plurality of memory blocks, wherein the second region 306 is a region at a corner of the memory block.

It is to be noted that FIG. 7 may be only a partial structural diagram of one memory block or one memory bank at the dashed line in FIG. 4. In the examples of the present disclosure, the first region 305 and the second region 306 may be regions in the dummy region, and an arrangement direction of the first region 305 and the second region 306 is the same as an extending direction of the first conductive line 303, and the second region 306 is located at the corner of the memory bank or at the corner of the memory block.

In the examples of the present disclosure, the sizes of the semiconductor bodies at the corners of some of the memory blocks in the second direction may be optimized accordingly, for example, the semiconductor bodies at the corners of the memory banks are optimized accordingly; or the sizes of the semiconductor bodies at the corners of all of the memory blocks in the second direction may be optimized accordingly. A corresponding selection may be made in a comprehensive consideration of both the space required by the corresponding conductive connection structure and the influence of the loading effect.

In the examples of the present disclosure, the size of the third semiconductor body 302 in the second region 306 at the corner of the memory bank or in the second region 306 at the corner of the memory block in the second direction is set between the size of the first semiconductor body 300 in the second direction and the size of the second semiconductor body 301 in the second direction, such that the environmental difference between the second region 306 and the first region 305 is reduced, thereby reducing the loading effect during an etching process and solving the problem of failure in cutting off a final initial word line due to the etch loading effect.

In some examples, as shown in FIG. 8, the memory device further comprises a third region 307 that is located between the first region 305 and the second region 306, and some of the plurality of first semiconductor bodies 300 are located in the third region 307. The memory device further comprises a plurality of fourth semiconductor bodies 308 that each extend in the first direction and the second direction and are arranged in the third direction in the third region 307. The first semiconductor bodies 300 and the fourth semiconductor bodies 308 in the third region 307 are arranged alternately in the second direction, and the size of the fourth semiconductor body 308 in the second direction is greater than the size of the second semiconductor body 301 in the second direction and is less than or equal to the size of the third semiconductor body 302 in the second direction.

In the examples of the present disclosure, the size of the fourth semiconductor body 308 in the third region 307 in the second direction is less than or equal to the size of the third semiconductor body 302 in the second direction, which may include several scenarios: I, the sizes of the fourth semiconductor bodies 308 in the third region 307 in the second direction may be all less than the size of the third semiconductor body 302 in the second direction; II, sizes of some of the plurality of fourth semiconductor bodies 308 in the third region 307 close to the first region 305 in the second direction are less than the size of the third semiconductor body 302 in the second direction, and sizes of some of the plurality of fourth semiconductor bodies 308 in the third region 307 close to the second region 306 in the second direction are equal to the size of the third semiconductor body 302 in the second direction; and III, the sizes of the fourth semiconductor bodies 308 in the third region 307 are all equal to the size of the third semiconductor body 302 in the second direction.

In the examples of the present disclosure, the size of the fourth semiconductor body 308 in the third region 307 in the second direction is set to be greater than the size of the second semiconductor body 301 in the first region 305 in the second direction, such that the difference between the first region and the surrounding environment may be further reduced, thereby further reducing the loading effect during the etching process.

In some examples, as shown in FIG. 8, in a direction from the first region 305 toward the second region 306, the sizes of the plurality of fourth semiconductor bodies 308 increase sequentially in the second direction; or as shown in FIG. 9, in the direction from the first region 305 toward the second region 306, sizes of some of the plurality of fourth semiconductor bodies 308 close to the first region 305 increase sequentially in the second direction, and sizes of some of the plurality of fourth semiconductor bodies 308 away from the first region 305 are equal in the second direction.

In the above examples, the direction from the first region 305 toward the second region 306 may be a direction indicated by an arrow as shown in FIGS. 8 and 9. In the direction from the first region 305 toward the second region 306, the sizes of at least some of the plurality of fourth semiconductor bodies 308 in the third region 307 in the second direction are set to increase sequentially, such that the difference between the second region and the surrounding environment may be further reduced, thereby further reducing the loading effect during the etching process.

In some examples, as shown in FIGS. 8 and 9, the sizes of the plurality of third semiconductor bodies 302 in the second direction are equal, and are equal to the size of the fourth semiconductor body 308 closest to the third semiconductor body 302 in the second direction.

In the examples of the present disclosure, the sizes of the plurality of third semiconductor bodies 302 in the second direction are equal, and may be equal to or greater than the size of the fourth semiconductor body 308 closest to the third semiconductor body 302 in the second direction.

In some examples, the sizes of the plurality of first semiconductor bodies 300 in the second direction are equal, and the sizes of the plurality of second semiconductor bodies 301 in the second direction are equal.

It is to be noted that the sizes of the plurality of third semiconductor bodies 302 in the second direction being equal means that the sizes of them are substantially equal within an allowable process error range; the sizes of the plurality of first semiconductor bodies 300 in the second direction being equal means that the sizes of them are substantially equal within an allowable process error range; and the sizes of the plurality of second semiconductor bodies 301 in the second direction being equal means that the sizes of them are substantially equal within an allowable process error range.

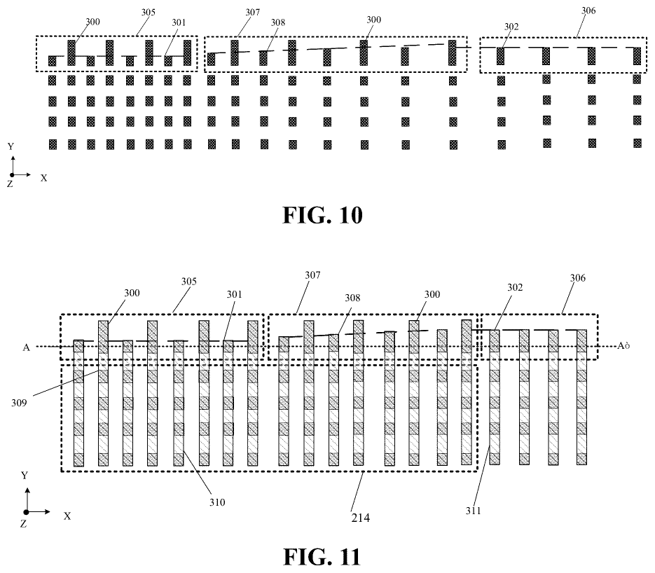

In some examples, as shown in FIG. 10, a distance between two adjacent ones of the third semiconductor bodies 302 in the second region 306 is greater than a distance between the first semiconductor body 300 and second semiconductor body 301 that are adjacent to each other in the first region 305.

In the above examples, on the basis of optimizing the size of the third semiconductor body 302 in the second region 306 in the second direction, the distance between two adjacent ones of the third semiconductor bodies 302 in the second region 306 is also optimized accordingly. In an example, the distance between two adjacent ones of the third semiconductor bodies 302 in the second region 306 and the distance between the first semiconductor body 300 and second semiconductor body 301 that are adjacent to each other in the first region 305 are set differently, and the distance between two adjacent ones of the third semiconductor bodies 302 in the second region 306 is set to be larger, such that the difference between the second region 306 and the surrounding environment may be further reduced, thereby further reducing the loading effect during the etching process.

In some examples, a distance between the first semiconductor body 300 and fourth semiconductor body 308 that are adjacent to each other in the third region 307 is greater than the distance between the first semiconductor body 300 and second semiconductor body 301 that are adjacent to each other in the first region 305, and is less than or equal to the distance between adjacent ones of the third semiconductor bodies 302 in the second region 306.

In the examples of the present disclosure, the distance between the first semiconductor body 300 and fourth semiconductor body 308 that are adjacent to each other in the third region 307 being less than or equal to the distance between adjacent ones of the third semiconductor bodies 302 in the second region 306 may include several scenarios: I, the distances between the first semiconductor bodies 300 and fourth semiconductor bodies 308 that are adjacent to each other in the third region 307 are all less than the distance between adjacent ones of the third semiconductor bodies 302 in the second region 306; II, the distances between the first semiconductor bodies 300 and fourth semiconductor bodies 308 that are adjacent to each other in the third region 307 are all equal to the distance between adjacent ones of the third semiconductor bodies 302 in the second region 306; and III, the distance between the first semiconductor body 300 and fourth semiconductor body 308 that are adjacent to each other in the third region 307 close to the first region 305 is less than the distance between adjacent ones of the third semiconductor bodies 302 in the second region 306, and the distance between the first semiconductor body 300 and fourth semiconductor body 308 that are adjacent to each other in the third region 307 close to the second region 306 is equal to the distance between adjacent ones of the third semiconductor bodies 302 in the second region 306.

In the above examples, the distance between the first semiconductor body 300 and fourth semiconductor body 308 that are adjacent to each other in the third region 307 is optimized accordingly, such that the difference between the second region 306 and the surrounding environment may be further reduced, thereby further reducing the loading effect during the etching process.

In some examples, in the direction from the first region 305 toward the second region 306, the distances between the first semiconductor bodies 300 and fourth semiconductor bodies 308 that are adjacent to each other in the third region 307 increase sequentially.

In the above examples, the distance between the first semiconductor body 300 and fourth semiconductor body 308 that are adjacent to each other in the third region 307 is further optimized, such that on the basis of saving the area of the memory device, the difference between the second region 306 and the surrounding environment may be further reduced, thereby further reducing the loading effect during the etching process.

In some examples, in the direction from the first region 305 toward the second region 306, the distances between adjacent ones of the third semiconductor bodies 302 in the second region 306 increase sequentially; or the distances between adjacent ones of the third semiconductor bodies 302 in the second region 306 are equal.

In some particular examples, the distances between adjacent ones of some of the plurality of third semiconductor bodies 302 in the second region 306 close to the first region 305 increase sequentially in the direction from the first region 305 toward the second region 306, and the distances between adjacent ones of some of the plurality of third semiconductor bodies 302 in the second region 306 away from the first region 305 are equal.

In some examples, the distance between the first semiconductor body 300 and fourth semiconductor body 308 that are adjacent to each other in the third region 307 is D1, the distance between the first semiconductor body 300 and second semiconductor body 301 that are adjacent to each other in the first region 305 is D2, and the range of (D1−D2)/D2 is 0-50%. The distance between adjacent ones of the third semiconductor bodies 302 in the second region 306 is D3, and the range of (D3−D2)/D2 is 0-50%.

It is to be noted that the ranges of (D1−D2)/D2 and (D3−D2)/D2 given in the above examples are merely examples, and are not intended to limit the ranges of (D1−D2)/D2 and (D3−D2)/D2 in the examples of the present disclosure. In some particular examples, the ranges of (D1−D2)/D2 and (D3−D2)/D2 may be set in conjunction with the area of the memory and the etch loading effect.

In some examples, the distances between the first semiconductor bodies 300 and second semiconductor bodies 301 that are adjacent to each other in the first region 305 are equal.

It is to be noted that the distances between the first semiconductor bodies 300 and second semiconductor bodies 301 that are adjacent to each other in the first region 305 being equal means that the distances between the first semiconductor bodies 300 and second semiconductor bodies 301 that are adjacent to each other in the first region 305 are substantially equal within an allowable process error range.

In some examples, as shown in FIG. 11, the memory device further comprises a plurality of second conductive lines 309, a plurality of third conductive lines 310 and a plurality of fourth conductive lines 311 that each extend in the second direction and are arranged in the third direction. One of two opposite ends of one first semiconductor body 300 in the first direction is connected with one second conductive line 309; one of two opposite ends of one second semiconductor body 301 in the first direction is connected with one third conductive line 310; one of two opposite ends of one third semiconductor body 302 in the first direction is connected with one fourth conductive line 311; and a size of part of the fourth conductive line 311 in the second region 306 in the second direction is greater than a size of part of the third conductive line 310 in the first region 305 in the second direction, and is less than a size of part of the second conductive line 309 in the first region 305 in the second direction.

In some examples, as shown in FIG. 11, one of two opposite sides of the second conductive line 309 correspondingly connected with the first semiconductor body 300 in the second direction away from the memory region 214 is aligned with one of two opposite sides of the first semiconductor body 300 in the second direction away from the memory region 214; one of two opposite sides of the third conductive line 310 correspondingly connected with the second semiconductor body 301 in the second direction away from the memory region 214 is aligned with one of two opposite sides of the second semiconductor body 301 in the second direction away from the memory region 214; and one of two opposite sides of the fourth conductive line 311 correspondingly connected with the third semiconductor body 302 in the second direction away from the memory region 214 is aligned with one of two opposite sides of the third semiconductor body 302 in the second direction away from the memory region 214.

In some other examples, sizes of some of the plurality of second conductive lines 309 in the first region 305 in the second direction, sizes of some of the plurality of third conductive lines 310 in the first region 305 in the second direction and sizes of some of the plurality of fourth conductive lines 311 in the second region 306 in the second direction may be all equal.

The second conductive line 309, the third conductive line 310 and the fourth conductive line 311 may be bit lines in the memory device. Materials of the second conductive line 309, the third conductive line 310 and the fourth conductive line 311 may comprise a conductive material, including, but not limited to, a metal material and a metal silicide; the metal material includes, but is not limited to, tungsten, titanium, tantalum, aluminum, etc.; and the metal silicide includes, but is not limited to, tungsten silicide, nickel silicide, cobalt silicide, and titanium silicide.

In some particular examples, the distances between the second conductive lines 309, the third conductive lines 310 and the fourth conductive lines 311 in each region and the distances between the first semiconductor bodies 300, the second semiconductor bodies 301 and the third semiconductor bodies 302 correspondingly connected with them may maintain the same trend.

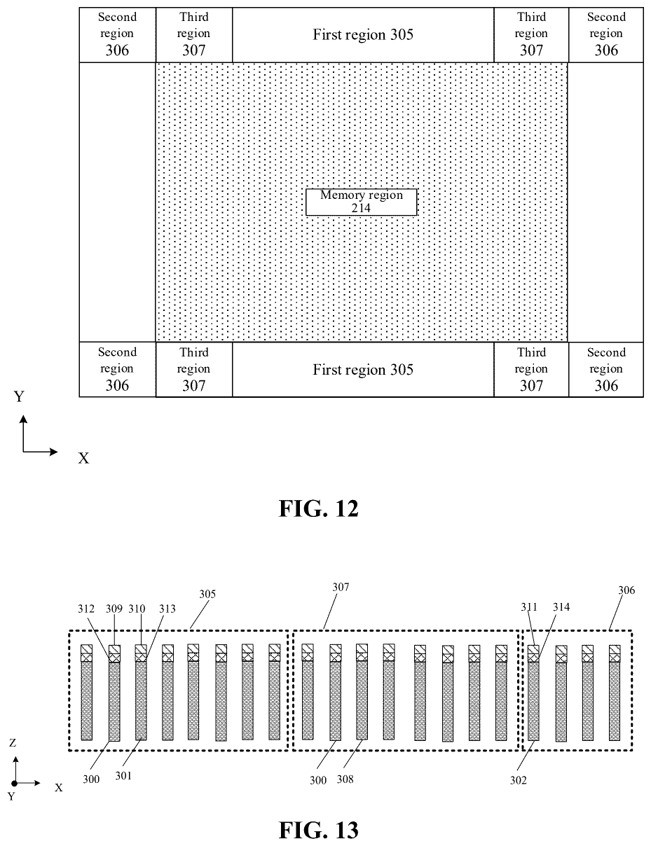

FIG. 12 is a composition structural diagram of a memory block. As shown in FIGS. 4 and 12, the memory block comprises a memory region 214 and a dummy region surrounding the memory region 214. The first region 305, the second region 306 and the third region 307 may be located in the dummy region on one of two opposite sides of the memory block in the second direction, or the first region 305, the second region 306 and the third region 307 may be disposed on both the two opposite sides of the memory block in the second direction. Moreover, for the first region 305, the second region 306 and the third region 307 on one of two opposite sides of the memory block in the second direction, the second region 306 may be located on two opposite sides of the first region 305 in the third direction, or the second region 306 may be located on two opposite sides of a unity consisting of the first region 305 and the third region 307 in the third direction, and the third region 307 may be located on two opposite sides of the first region 305 in the third direction. That is to say, in the examples of the present disclosure, the sizes of the semiconductor bodies in at least some of the four corners of the memory block in the second direction and the distance between the adjacent semiconductor bodies are optimized accordingly.

FIG. 13 is a cross-sectional structural diagram at the AA′ position in FIG. 11. In some examples, as shown in FIG. 13, the memory device further comprises a plurality of first semiconductor lines 312, a plurality of second semiconductor lines 313 and a plurality of third semiconductor lines 314 that extend in the second direction and are arranged in the third direction. The first semiconductor line 312 is located between the first semiconductor body 300 and the second conductive line 309; the second semiconductor line 313 is located between the second semiconductor body 301 and the third conductive line 310; the third semiconductor line 314 is located between the third semiconductor body 302 and the fourth conductive line 311; a size of the first semiconductor line 312 in the second direction is equal to a size of the second conductive line 309 in the second direction; a size of the second semiconductor line 313 in the second direction is equal to a size of the third conductive line 310 in the second direction; and a size of the third semiconductor line 314 in the second direction is equal to a size of the fourth conductive line 311 in the second direction.

In some particular examples, materials of the first semiconductor line 312, the second semiconductor line 313 and the third semiconductor line 314 are the same as the materials of the first semiconductor body 300, the second semiconductor body 301 and the third semiconductor body 302.

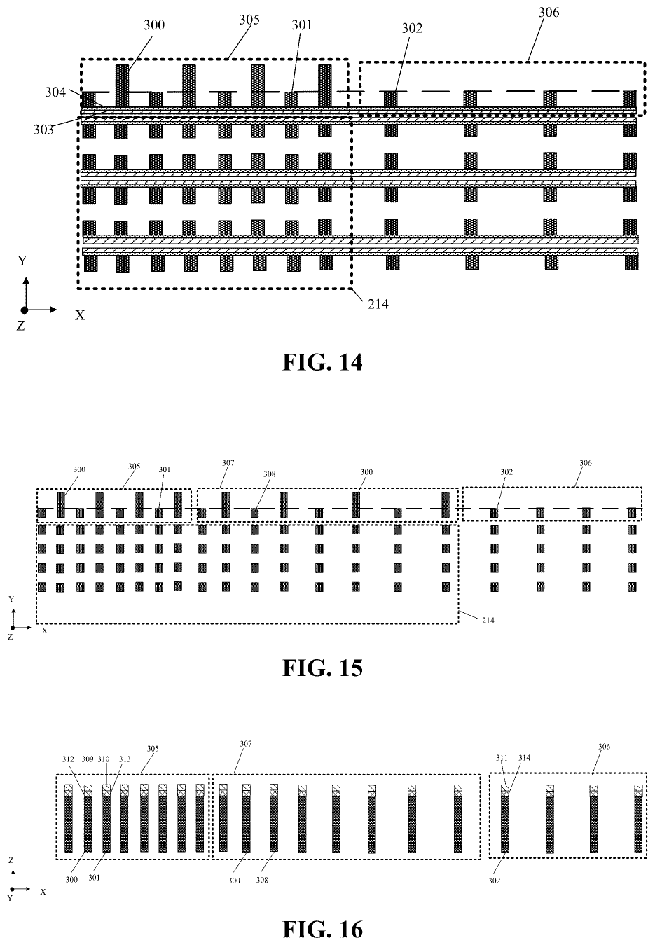

Based on a similar conception to the above-mentioned memory device, examples of the present disclosure further provide a memory device. FIG. 14 is a partial structural diagram of a memory device. As shown in FIG. 14, the memory device comprises a first region 305 and a second region 306. The first region 305 comprises a plurality of first semiconductor bodies 300 and a plurality of second semiconductor bodies 301; the second region 306 comprises a plurality of third semiconductor bodies 302; the plurality of first semiconductor bodies 300, the plurality of second semiconductor bodies 301 and the plurality of third semiconductor bodies 302 each extend in a first direction and a second direction and are arranged in a third direction; the plurality of first semiconductor bodies 300 and the plurality of second semiconductor bodies 301 are arranged alternately in the third direction; and the first region 305 and the second region 306 are arranged in juxtaposition in the third direction. The first region 305 and the second region 306 further comprise first conductive lines 303 extending in the third direction, and the first conductive lines 303 are at least located on one of two opposite sides of the plurality of first semiconductor bodies 300, the plurality of second semiconductor bodies 301 and the plurality of third semiconductor bodies 302 in the second direction. The second direction intersects the third direction, and both the second direction and the third direction are perpendicular to the first direction. A distance between two adjacent ones of the third semiconductor bodies 302 in the second region 306 is greater than a distance between the first semiconductor body 300 and second semiconductor body 301 that are adjacent to each other in the first region 305.

In the examples of the present disclosure, FIG. 14 may be a structural diagram at a dashed box B shown in FIG. 4. The first direction may be a Z axis direction shown in FIG. 14, the second direction may be a Y axis direction shown in the figure, and the third direction may be an X axis direction shown in the figure.

In some particular examples, materials of the first semiconductor body 300, the second semiconductor body 301, the third semiconductor body 302 and a fourth semiconductor body 308 include, but are not limited to, an elemental semiconductor material (e.g., silicon (Si) or germanium (Ge), etc.), a group III-V compound semiconductor material (e.g., gallium nitride (GaN), gallium arsenide (GaAs), or indium phosphide (InP), etc.), a group II-VI compound semiconductor material (e.g., zinc sulfide (ZnS), cadmium sulfide (CdS) or cadmium telluride (CdTe), etc.), an organic semiconductor material or other semiconductor materials known in the art. The materials of the first semiconductor body 300, the second semiconductor body 301, the third semiconductor body 302 and the fourth semiconductor body 308 are the same.

In the above examples of the present disclosure, the distance between two adjacent ones of the third semiconductor bodies 302 in the second region 306 is optimized accordingly; the distance between two adjacent ones of the third semiconductor bodies 302 in the second region 306 and the distance between the first semiconductor body 300 and second semiconductor body 301 that are adjacent to each other in the first region 305 are set differently; and the distance between two adjacent ones of the third semiconductor bodies 302 in the second region 306 is set to be larger, such that the difference between the second region 306 and the surrounding environment may be reduced, thereby reducing the loading effect during an etching process.

In some particular examples, as shown in FIG. 14, a gate dielectric layer 304 is further disposed between the first conductive line 303 and a corresponding semiconductor body, and may be located between the first conductive line 303 and a channel region of the corresponding semiconductor body. The gate dielectric layer 304 may comprise at least one of a high dielectric constant material, silicon oxide, silicon nitride and silicon oxynitride, and the high dielectric constant material may comprise at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some examples, as shown in FIG. 15, the memory device further comprises a third region 307 that is located between the first region 305 and the second region 306, and some of the plurality of first semiconductor bodies 300 are located in the third region 307. The memory device further comprises a plurality of fourth semiconductor bodies 308 that each extend in the first direction and the second direction and are arranged in the third direction in the third region 307. The first semiconductor bodies 300 and the fourth semiconductor bodies 308 in the third region 307 are arranged alternately in the third direction; a distance between the first semiconductor body 300 and fourth semiconductor body 308 that are adjacent to each other in the third region 307 is greater than the distance between the first semiconductor body 300 and second semiconductor body 301 that are adjacent to each other in the first region 305; and a distance between the first semiconductor body 300 and fourth semiconductor body 308 that are adjacent to each other in the third region 307 is less than or equal to the distance between adjacent ones of the third semiconductor bodies 302 in the second region 306.

In the examples of the present disclosure, the distance between the first semiconductor body 300 and fourth semiconductor body 308 that are adjacent to each other in the third region 307 being less than or equal to the distance between adjacent ones of the third semiconductor bodies 302 in the second region 306 may include several scenarios: I, the distances between the first semiconductor bodies 300 and fourth semiconductor bodies 308 that are adjacent to each other in the third region 307 are all less than the distance between adjacent ones of the third semiconductor bodies 302 in the second region 306; II, the distances between the first semiconductor bodies 300 and fourth semiconductor bodies 308 that are adjacent to each other in the third region 307 are all equal to the distance between adjacent ones of the third semiconductor bodies 302 in the second region 306; and III, the distance between the first semiconductor body 300 and fourth semiconductor body 308 that are adjacent to each other in the third region 307 close to the first region 305 is less than the distance between adjacent ones of the third semiconductor bodies 302 in the second region 306, and the distance between the first semiconductor body 300 and fourth semiconductor body 308 that are adjacent to each other in the third region 307 close to the second region 306 is equal to the distance between adjacent ones of the third semiconductor bodies 302 in the second region 306.

In the above examples, the distance between the first semiconductor body 300 and fourth semiconductor body 308 that are adjacent to each other in the third region 307 is optimized accordingly, such that the difference between the second region 306 and the surrounding environment may be further reduced, thereby further reducing the loading effect during the etching process.

In some examples, in the direction from the first region 305 toward the second region 306, the distances between the first semiconductor bodies 300 and fourth semiconductor bodies 308 that are adjacent to each other in the third region 307 increase sequentially.

In the above examples, the distance between the first semiconductor body 300 and fourth semiconductor body 308 that are adjacent to each other in the third region 307 is further optimized, such that on the basis of saving the area of the memory device, the difference between the second region 306 and the surrounding environment may be further reduced, thereby further reducing the loading effect during the etching process.

In some examples, in the direction from the first region 305 toward the second region 306, the distances between adjacent ones of the third semiconductor bodies 302 in the second region 306 increase sequentially; or the distances between adjacent ones of the third semiconductor bodies 302 in the second region 306 are equal.

In some particular examples, the distances between adjacent ones of some of the plurality of third semiconductor bodies 302 in the second region 306 close to the first region 305 increase sequentially in the direction from the first region 305 toward the second region 306, and the distances between adjacent ones of some of the plurality of third semiconductor bodies 302 in the second region 306 away from the first region 305 are equal.

In some examples, the distance between the first semiconductor body 300 and fourth semiconductor body 308 that are adjacent to each other in the third region 307 is D2, the distance between the first semiconductor body 300 and second semiconductor body 301 that are adjacent to each other in the first region 305 is D2, and the range of (D1−D2)/D2 is 0-50%. The distance between adjacent ones of the third semiconductor bodies 302 in the second region 306 is D3, and the range of (D3−D2)/D2 is 0-50%.

In some examples, the distances between the first semiconductor bodies 300 and second semiconductor bodies 301 that are adjacent to each other in the first region 305 are equal.

It is to be noted that the distances between the first semiconductor bodies 300 and second semiconductor bodies 301 that are adjacent to each other in the first region 305 being equal means that the distances between the first semiconductor bodies 300 and second semiconductor bodies 301 that are adjacent to each other in the first region 305 are substantially equal within an allowable process error range.

In some examples, as shown in FIG. 16, the memory device further comprises a plurality of second conductive lines 309, a plurality of third conductive lines 310 and a plurality of fourth conductive lines 311 that each extend in the second direction and are arranged in the third direction. One of two opposite ends of one of the first semiconductor bodies 300 in the first direction is connected with one of the second conductive lines 309; one of two opposite ends of one of the second semiconductor bodies 301 in the first direction is connected with one of the third conductive lines 310; one of two opposite ends of one of the third semiconductor bodies 302 in the first direction is connected with one of the fourth conductive lines 311; and a distance between two adjacent ones of the fourth conductive lines 311 is greater than a distance between the second conductive line 309 and third conductive line 310 that are adjacent to each other.

In some examples, the memory device comprises a plurality of memory banks, wherein the second region 306 is a region at a corner of the memory bank; or the memory device comprises a plurality of memory blocks, wherein the second region 306 is a region at a corner of the memory block.

In some examples, as shown in FIG. 16, the memory device further comprises a plurality of first semiconductor lines 312, a plurality of second semiconductor lines 313 and a plurality of third semiconductor lines 314 that extend in the second direction and are arranged in the third direction. The first semiconductor line 312 is located between the first semiconductor body 300 and the second conductive line 309; the second semiconductor line 313 is located between the second semiconductor body 301 and the third conductive line 310; the third semiconductor line 314 is located between the third semiconductor body 302 and the fourth conductive line 311; and a distance between two adjacent ones of the third semiconductor lines 314 is greater than a distance between the first semiconductor line 312 and second semiconductor line 313 that are adjacent to each other.

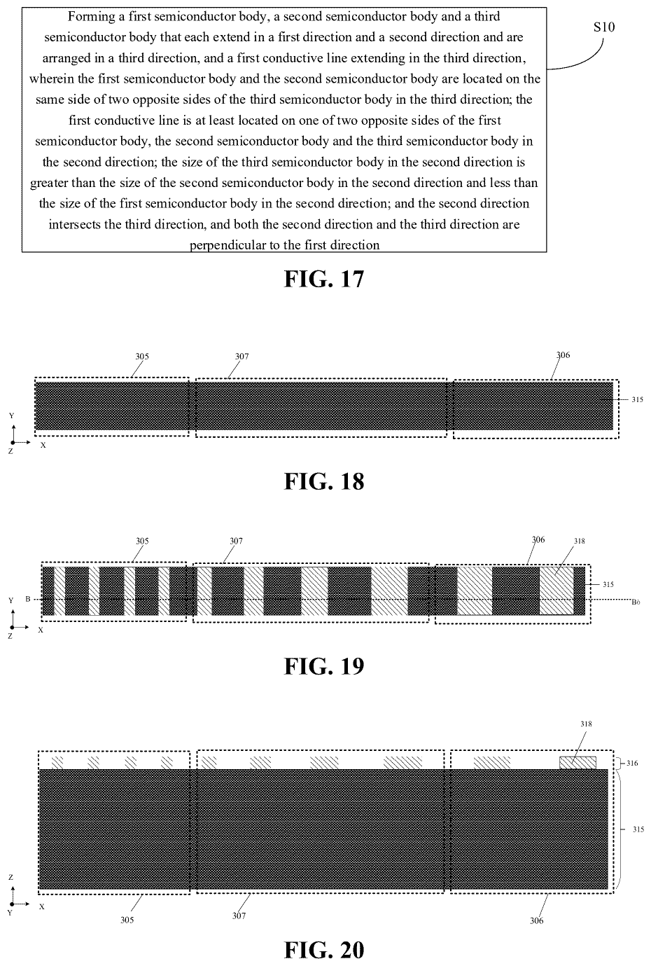

Based on above-mentioned memory device, examples of the present disclosure further provide a manufacturing method of a memory device. FIG. 17 is a flow diagram of a manufacturing method of a memory device provided by examples of the present disclosure. As shown in FIG. 17, the manufacturing method of the memory device comprises:

S10: forming a first semiconductor body, a second semiconductor body and a third semiconductor body that each extend in a first direction and a second direction and are arranged in a third direction, and a first conductive line extending in the third direction. The first semiconductor body and the second semiconductor body are located on the same side of two opposite sides of the third semiconductor body in the third direction; the first conductive line is at least located on one of two opposite sides of the first semiconductor body, the second semiconductor body and the third semiconductor body in the second direction; the size of the third semiconductor body in the second direction is greater than the size of the second semiconductor body in the second direction and less than the size of the first semiconductor body in the second direction; and the second direction intersects the third direction, and both the second direction and the third direction are perpendicular to the first direction.

In some examples, the memory device comprises a first region and a second region that are arranged in juxtaposition in the second direction, and comprises a plurality of the first semiconductor bodies, a plurality of the second semiconductor bodies and a plurality of the third semiconductor bodies. The plurality of first semiconductor bodies and the plurality of second semiconductor bodies are located in the first region, the plurality of third semiconductor bodies are located in the second region, and the plurality of first semiconductor bodies and the plurality of second semiconductor bodies are arranged alternately in the second direction.

In some examples, the memory device comprises a plurality of memory banks, wherein the second region 306 is a region at a corner of the memory bank; or the memory device comprises a plurality of memory blocks, wherein the second region 306 is a region at a corner of the memory block.

FIGS. 18 to 27 are structural diagrams of a fabrication process of a memory device provided by examples of the present disclosure. The manufacturing method of the memory device provided by the examples of the present disclosure will be introduced below in conjunction with FIGS. 18 to 27.

It is to be noted that FIGS. 18 to 27 are only illustrative structural diagrams of a formation process of a structure corresponding to the dashed box A in FIG. 4. In the examples of the present disclosure, the first region 305 and the second region 306 may be regions in a dummy region, and an arrangement direction of the first region 305 and the second region 306 is the same as an extending direction of the first conductive line, and the second region 306 is located at a corner of a memory bank or at a corner of a memory block.

In some examples, forming the plurality of first semiconductor bodies, the plurality of second semiconductor bodies and the plurality of third semiconductor bodies comprises: providing a plurality of initial first semiconductor bodies and a plurality of initial second semiconductor bodies in the first region and a plurality of initial third semiconductor bodies in the second region. The plurality of initial first semiconductor bodies, the plurality of initial second semiconductor bodies and the plurality of initial third semiconductor bodies each extend in the first direction and the second direction and are arranged in the third direction, and the plurality of initial first semiconductor bodies and the plurality of initial second semiconductor bodies are arranged alternately in the third direction.

In some examples, the memory device further comprises a third region located between the first region and the second region.

In some examples, some of the plurality of initial first semiconductor bodies are located in the third region. The method further comprises: providing a plurality of initial fourth semiconductor bodies that each extend in the first direction and the second direction and are arranged in the third direction in the third region.

FIGS. 18 to 24 are structural diagrams of forming the plurality of initial first semiconductor bodies, the plurality of initial second semiconductor bodies, the plurality of initial third semiconductor bodies and the plurality of initial fourth semiconductor bodies. Further introduction will be made below in conjunction with FIGS. 18 to 24.

In some examples, forming the plurality of initial first semiconductor bodies, the plurality of initial second semiconductor bodies, the plurality of initial third semiconductor bodies and the plurality of initial fourth semiconductor bodies comprises: as shown in FIG. 18, providing an initial semiconductor layer 315 in the first region 305, the second region 306 and the third region 307, wherein FIG. 20 is a cross-sectional structural diagram at BB′ in FIG. 19; and as shown in FIGS. 19 and 20, forming a second mask layer 316 on the initial semiconductor layer 315, wherein a second mask pattern is formed in the second mask layer 316 and comprises a plurality of mask lines 318 that extend in the second direction and are arranged in the third direction, a distance between two adjacent ones of the mask lines 318 in the second region 306 is greater than a distance between adjacent ones of the mask lines 318 in the first region 305, and the size of the mask line 318 in the second region 306 in the third direction is greater than the size of the mask line 318 in the first region 305 in the third direction.

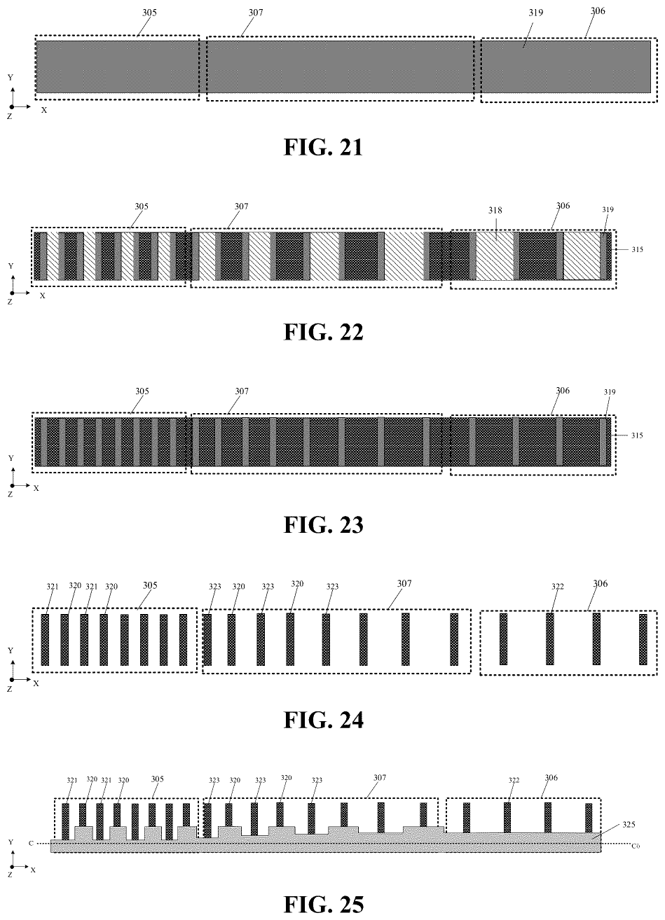

In some examples, forming the plurality of initial first semiconductor bodies, the plurality of initial second semiconductor bodies, the plurality of initial third semiconductor bodies and the plurality of initial fourth semiconductor bodies further comprises: as shown in FIG. 21, forming a third mask layer 319 conformally covering the second mask layer 316 and the initial semiconductor layer 315; as shown in FIG. 22, removing part of the third mask layer 319 with a remaining part of the third mask layer 319 covering sidewalls of the mask lines 318; as shown in FIG. 23, removing the mask lines 318 in the second mask layer 316; and as shown in FIG. 24, etching the initial semiconductor layer 315 using the remaining part of the third mask layer 319 as a mask to form the plurality of initial first semiconductor bodies 320, the plurality of initial second semiconductor bodies 321, the plurality of initial third semiconductor bodies 322 and the plurality of initial fourth semiconductor bodies 323.

In some examples, the initial first semiconductor bodies 320 and the initial fourth semiconductor bodies 323 in the third region 307 are arranged alternately in the third direction.

In some examples, a distance between adjacent ones of the mask lines 318 in the third region 307 is greater than a distance between adjacent ones of the mask lines 318 in the first region 305, and the size of the mask line 318 in the third region 307 in the third direction is greater than the size of the mask line 318 in the first region 305 in the third direction. The distance between adjacent ones of the mask lines 318 in the third region 307 is less than or equal to a distance between adjacent ones of the mask lines 318 in the second region 306, and the size of the mask line 318 in the third region 307 in the third direction is less than or equal to the size of the mask line 318 in the second region 306 in the third direction.

In some examples, in a direction from the first region 305 toward the second region 306, the distances between adjacent ones of the mask lines 318 in the third region 307 increase sequentially, and the sizes of the mask lines 318 in the third region 307 in the third direction increase sequentially.

In some examples, in the direction from the first region 305 toward the second region 306, the distances between adjacent ones of the mask lines 318 in the second region 306 increase sequentially, and the sizes of the mask lines 318 in the second region 306 in the third direction increase sequentially; or the distances between adjacent ones of the mask lines 318 in the second region 306 are equal, and the sizes of the mask lines 318 in the second region 306 in the third direction are equal.

FIGS. 25 to 27 are structural diagrams of forming the plurality of first semiconductor bodies, the plurality of second semiconductor bodies, the plurality of third semiconductor bodies and the plurality of fourth semiconductor bodies on the basis of the plurality of initial first semiconductor bodies, the plurality of initial second semiconductor bodies, the plurality of initial third semiconductor bodies and the plurality of initial fourth semiconductor bodies. Further introduction will be made below in conjunction with FIGS. 25 to 27.

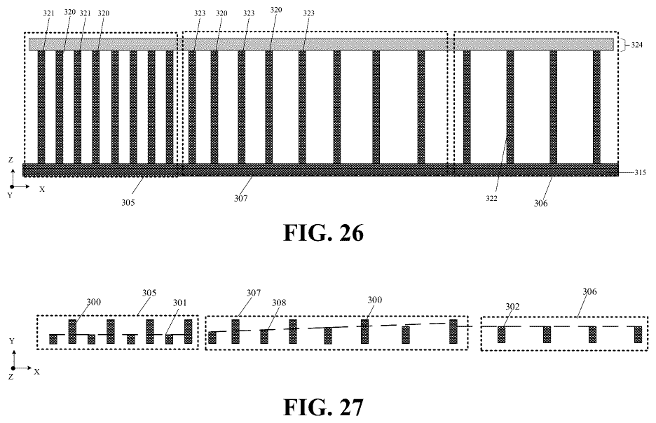

In some examples, forming the plurality of first semiconductor bodies, the plurality of second semiconductor bodies and the plurality of third semiconductor bodies further comprises: as shown in FIGS. 25 and 26 that is a cross-sectional structural diagram at CC′ of FIG. 25, forming a first mask layer 324 on the plurality of initial first semiconductor bodies 320, the plurality of initial second semiconductor bodies 321 and the plurality of initial third semiconductor bodies, wherein a first mask pattern 325 is formed in the first mask layer 324; the size of the first mask pattern 325 right above the initial third semiconductor body 322 in the second direction is greater than the size of the first mask pattern 325 right above the initial second semiconductor body 321 in the second direction, and is less than the size of the first mask pattern 325 right above the initial first semiconductor body 320 in the second direction.

As shown in FIG. 27, the plurality of initial first semiconductor bodies 320, the plurality of initial second semiconductor bodies 321 and the plurality of initial third semiconductor bodies are etched based on the first mask pattern 325, to form the plurality of first semiconductor bodies 300, the plurality of second semiconductor bodies 301 and the plurality of third semiconductor bodies 302.

In some examples, as shown in FIGS. 25 and 26, the first mask layer 324 is formed on the plurality of initial fourth semiconductor bodies 323 while the first mask layer 324 is formed on the plurality of initial first semiconductor bodies 320, the plurality of initial second semiconductor bodies 321 and the plurality of initial third semiconductor bodies. The size of the first mask pattern 325 right above the initial fourth semiconductor body 323 in the second direction is greater than the size of the first mask pattern 325 right above the initial second semiconductor body 321 in the second direction, and is less than or equal to the size of the first mask pattern 325 right above the initial third semiconductor body 322 in the second direction.

In the examples of the present disclosure, the above-mentioned initial semiconductor layer 315, the second mask layer 316, the third mask layer 319 and the first mask layer 324 may be formed by a deposition process.

In examples of the present disclosure, the deposition process includes, but is not limited to, Chemical Vapor Deposition (CVD), Low Pressure Chemical Vapor Deposition (LPCVD), Plasma Enhanced Chemical Vapor Deposition (PECVD), Physical Vapor Deposition (PVD), and Atomic Layer Deposition (ALD). The etching process includes, but is not limited to, Plasma Etching (PE), Sputtering Etching (SE), Ion Beam Etching (IBE) and Reactive Ion Etching (RIE).

In some particular examples, the initial semiconductor layer comprises a first side and a second side that are opposite in a thickness direction of the initial semiconductor layer. The above formation of the initial first semiconductor body, the initial second semiconductor body, the initial third semiconductor body and the initial fourth semiconductor body may be performed from the first side of the initial semiconductor layer. A process of FIGS. 25 to 27 may be performed from the first side of the initial semiconductor layer or from the second side of the initial semiconductor layer. As shown in FIG. 26, after the first semiconductor body, the second semiconductor body, the third semiconductor body and the fourth semiconductor body are formed, there is still part of the initial semiconductor layer 315 at the bottoms of the first semiconductor body, the second semiconductor body, the third semiconductor body and the fourth semiconductor body. During a subsequent process, the initial semiconductor layer 315 may be thinned from the second side of the initial semiconductor layer 315, to remove the initial semiconductor layer 315 at the bottoms of the first semiconductor body, the second semiconductor body, the third semiconductor body and the fourth semiconductor body.

In some examples, in the direction from the first region 305 toward the second region 306, the sizes of the first mask pattern 325 right above the plurality of initial fourth semiconductor bodies 323 increase sequentially in the second direction; or in the direction from the first region 305 toward the second region 306, the sizes of the first mask pattern 325 right above some of the plurality of initial fourth semiconductor bodies 323 close to the first region 305 increase sequentially in the second direction, and the sizes of the first mask pattern 325 right above some of the plurality of initial fourth semiconductor bodies 323 away from the first region 305 are equal in the first direction.

In some examples, the sizes of the first mask pattern 325 right above the plurality of initial third semiconductor bodies 322 in the second direction are equal, and the sizes of the first mask pattern 325 right above the plurality of initial third semiconductor bodies 322 in the second direction are equal to the sizes of the first mask pattern 325 right above the initial fourth semiconductor bodies 323 closest to the initial third semiconductor bodies 322 in the second direction.

The features disclosed in several device examples provided by the present disclosure may be combined arbitrarily to obtain a new device example in the case of no conflicts.

The methods disclosed in several method examples provided by the present disclosure can be combined arbitrarily to obtain a new method example in case of no conflicts.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory device, comprising:
a first semiconductor body, a second semiconductor body and a third semiconductor body that each extend in a first direction and a second direction and are arranged in a third direction; and
a first conductive line extending in the third direction,
wherein the first semiconductor body and the second semiconductor body are located on a same side of two opposite sides of the third semiconductor body in the third direction,
wherein the first conductive line is at least located on one of two opposite sides of the first semiconductor body, the second semiconductor body and the third semiconductor body in the second direction,
wherein a size of the third semiconductor body in the second direction is greater than a size of the second semiconductor body in the second direction, and is less than a size of the first semiconductor body in the second direction, and
wherein the second direction intersects the third direction, and both the second direction and the third direction are perpendicular to the first direction.

2. The memory device of claim 1, comprising a first region and a second region arranged in juxtaposition in the third direction,
wherein the memory device comprises a plurality of first semiconductor bodies including the first semiconductor body, a plurality of second semiconductor bodies including the second semiconductor body, and a plurality of third semiconductor bodies including the third semiconductor body, which are arranged in the third direction, and
wherein the plurality of first semiconductor bodies and the plurality of second semiconductor bodies are located in the first region, the plurality of third semiconductor bodies are located in the second region, and the plurality of first semiconductor bodies and the plurality of second semiconductor bodies are arranged alternately in the third direction.

3. The memory device of claim 2, further comprising a third region that is located between the first region and the second region, wherein one or more first semiconductor bodies of the plurality of first semiconductor bodies are located in the third region,
wherein the memory device further comprises a plurality of fourth semiconductor bodies that each extend in the first direction and the second direction and are arranged in the third direction in the third region, wherein the one or more first semiconductor bodies and the plurality of fourth semiconductor bodies in the third region are arranged alternately in the third direction, and wherein a size of a fourth semiconductor body in the second direction is greater than the size of the second semiconductor body in the second direction, and is smaller than or equal to the size of the third semiconductor body in the second direction.

4. The memory device of claim 3, wherein:
in a direction from the first region toward the second region, sizes of the plurality of fourth semiconductor bodies increase sequentially in the second direction, or
in the direction from the first region toward the second region, sizes of one or more fourth semiconductor bodies of the plurality of fourth semiconductor bodies close to the first region increase sequentially in the second direction, and sizes of one or more other fourth semiconductor bodies of the plurality of fourth semiconductor bodies away from the first region are equal in the second direction.

5. The memory device of claim 4, wherein sizes of the plurality of third semiconductor bodies in the second direction are equal, and the sizes of the plurality of third semiconductor bodies in the second direction are equal to the size of the fourth semiconductor body closest to the third semiconductor body in the second direction.

6. The memory device of claim 2, wherein sizes of the plurality of first semiconductor bodies in the second direction are equal, and sizes of the plurality of second semiconductor bodies in the second direction are equal.

7. The memory device of claim 2, wherein:
the memory device comprises a plurality of memory banks, and the second region is a region at a corner of a corresponding memory bank of the plurality of memory banks, or
the memory device comprises a plurality of memory blocks, and the second region is a region at a corner of a corresponding memory block of the plurality of memory blocks.

8. The memory device of claim 3, wherein a distance between two adjacent ones of the third semiconductor bodies in the second region is greater than a distance between the first semiconductor body and the second semiconductor body that are adjacent to each other in the first region.

9. The memory device of claim 8, wherein a distance between the first semiconductor body and the fourth semiconductor body that are adjacent to each other in the third region is greater than the distance between the first semiconductor body and the second semiconductor body that are adjacent to each other in the first region, and is smaller than or equal to a distance between adjacent ones of the third semiconductor bodies in the second region.

10. The memory device of claim 9, wherein, in a direction from the first region toward the second region, distances between first semiconductor bodies and fourth semiconductor bodies that are adjacent to each other in the third region increase sequentially.

11. The memory device of claim 9, wherein, in a direction from the first region toward the second region,
distances between adjacent ones of the third semiconductor bodies in the second region increase sequentially, or
distances between adjacent ones of the third semiconductor bodies in the second region are equal.

12. The memory device of claim 9, wherein the distance between the first semiconductor body and the fourth semiconductor body that are adjacent to each other in the third region is D1, the distance between the first semiconductor body and the second semiconductor body that are adjacent to each other in the first region is D2, and a range of (D1−D2)/D2 is 0-50%, and the distance between adjacent ones of the third semiconductor bodies in the second region is D3, and a range of (D3−D2)/D2 is 0-50%.

13. The memory device of claim 8, wherein distances between the first semiconductor bodies and the second semiconductor bodies that are adjacent to each other in the first region are equal.

14. The memory device of claim 2, further comprising:
a plurality of second conductive lines, a plurality of third conductive lines and a plurality of fourth conductive lines that each extend in the second direction and are arranged in the third direction,
wherein one of two opposite ends of one of the first semiconductor bodies in the first direction is connected with one of the second conductive lines, one of two opposite ends of one of the second semiconductor bodies in the first direction is connected with one of the third conductive lines, one of two opposite ends of one of the third semiconductor bodies in the first direction is connected with one of the fourth conductive lines, and a size of part of the fourth conductive line in the second region in the second direction is greater than a size of part of the third conductive line in the first region in the second direction, and is less than a size of part of the second conductive line in the first region in the second direction.

15. The memory device of claim 14, further comprising:
a plurality of first semiconductor lines, a plurality of second semiconductor lines and a plurality of third semiconductor lines that extend in the second direction and are arranged in the third direction,
wherein the first semiconductor line is located between the first semiconductor body and the second conductive line, the second semiconductor line is located between the second semiconductor body and the third conductive line, and the third semiconductor line is located between the third semiconductor body and the fourth conductive line, and
wherein a size of the first semiconductor line in the second direction is equal to a size of the second conductive line in the second direction, a size of the second semiconductor line in the second direction is equal to a size of the third conductive line in the second direction, and a size of the third semiconductor line in the second direction is equal to a size of the fourth conductive line in the second direction.

16. A memory device, comprising:
a first region; and
a second region,
wherein the first region comprises a plurality of first semiconductor bodies and a plurality of second semiconductor bodies, and the second region comprises a plurality of third semiconductor bodies,
wherein the plurality of first semiconductor bodies, the plurality of second semiconductor bodies, and the plurality of third semiconductor bodies each extend in a first direction and a second direction and are arranged in a third direction,
wherein the plurality of first semiconductor bodies and the plurality of second semiconductor bodies are arranged alternately in the third direction,
wherein the first region and the second region are arranged in juxtaposition in the third direction, and wherein the first region and the second region further comprise first conductive lines extending in the third direction, and the first conductive lines are at least located on one of two opposite sides of the plurality of first semiconductor bodies, the plurality of second semiconductor bodies and the plurality of third semiconductor bodies in the second direction,
wherein the second direction intersects the third direction, and both the second direction and the third direction are perpendicular to the first direction; and
wherein a distance between two adjacent ones of the third semiconductor bodies in the second region is greater than a distance between the first semiconductor body and the second semiconductor body that are adjacent to each other in the first region.

17. The memory device of claim 16, further comprising a third region that is located between the first region and the second region, wherein one or more first semiconductor bodies of the plurality of first semiconductor bodies are located in the third region,
wherein the memory device further comprises a plurality of fourth semiconductor bodies that each extend in the first direction and the second direction and are arranged in the third direction in the third region, wherein the first semiconductor bodies and the fourth semiconductor bodies in the third region are arranged alternately in the third direction, and
wherein a distance between the first semiconductor body and the fourth semiconductor body that are adjacent to each other in the third region is greater than the distance between the first semiconductor body and the second semiconductor body that are adjacent to each other in the first region, and is smaller than or equal to a distance between adjacent ones of the third semiconductor bodies in the second region.

18. The memory device of claim 17, wherein, in a direction from the first region toward the second region, distances between the first semiconductor bodies and the fourth semiconductor bodies that are adjacent to each other in the third region increase sequentially, and
wherein, in a direction from the first region toward the second region, distances between adjacent ones of the third semiconductor bodies in the second region increase sequentially, or distances between adjacent ones of the third semiconductor bodies in the second region are equal.

19. The memory device of claim 16, further comprising:
a plurality of second conductive lines, a plurality of third conductive lines and a plurality of fourth conductive lines that each extend in the second direction and are arranged in the third direction,
wherein one of two opposite ends of one of the first semiconductor bodies in the first direction is connected with one of the second conductive lines, one of two opposite ends of one of the second semiconductor bodies in the first direction is connected with one of the third conductive lines, one of two opposite ends of one of the third semiconductor bodies in the first direction is connected with one of the fourth conductive lines, and a distance between two adjacent ones of the fourth conductive lines is greater than a distance between the second conductive line and the third conductive line that are adjacent to each other.

20. A manufacturing method of a memory device, comprising:
forming a first semiconductor body, a second semiconductor body and a third semiconductor body that each extend in a first direction and a second direction and are arranged in a third direction; and
forming a first conductive line extending in the third direction,
wherein the first semiconductor body and the second semiconductor body are located on a same side of two opposite sides of the third semiconductor body in the third direction; the first conductive line is at least located on one of two opposite sides of the first semiconductor body, the second semiconductor body and the third semiconductor body in the second direction; a size of the third semiconductor body in the second direction is greater than a size of the second semiconductor body in the second direction, and is less than a size of the first semiconductor body in the second direction; and the second direction intersects the third direction, and both the second direction and the third direction are perpendicular to the first direction.
